(19) United States
(12) Patent Application Publication
(10) Pub. No.: US 2024/0353480 A1
(43) Pub. Date: Oct. 24, 2024

(54) METHODS AND APPARATUS FOR VOLTAGE CONTRAST DEFECT INSPECTION

(71) Applicants: Peter James O'Brien, Portland, OR (US); Bradley Robert Yates, Portland, OR (US); Joshua Marcus Yablon, Hillsboro, OR (US); Mark Joseph Koeper, Beaverton, OR (US); Mario Jesus Olmedo, Chandler, AZ (US); Oumarou Mbombo Njoya, Hillsboro, OR (US); Evelyn Sze Wing Chin, Hillsboro, OR (US)

(72) Inventors: Peter James O'Brien, Portland, OR (US); Bradley Robert Yates, Portland, OR (US); Joshua Marcus Yablon, Hillsboro, OR (US); Mark Joseph Koeper, Beaverton, OR (US); Mario Jesus Olmedo, Chandler, AZ (US); Oumarou Mbombo Njoya, Hillsboro, OR (US); Evelyn Sze Wing Chin, Hillsboro, OR (US)

(21) Appl. No.: 18/756,801

(22) Filed: Jun. 27, 2024

(51) Int. Cl. G01R 31/28

(52) U.S. Cl. CPC G01R 31/2884

(57) ABSTRACT

Methods and apparatus for voltage contrast defect inspection are disclosed. An example apparatus includes a substrate. The example apparatus further includes a virtual ground layer coupled to the substrate. The example apparatus also includes at least one process layer coupled to the virtual ground layer, the at least one process layer including a conductive feature.

### FIELD OF THE DISCLOSURE

This disclosure relates generally to integrated circuits and, more particularly, to methods and apparatus for voltage contrast defect inspection.

### BACKGROUND

Semiconductor device fabrication includes various processes to manufacture integrated circuits or chips. Depending on the materials and/or techniques involved, some fabrication processes may produce defects (e.g., process failures) in a completed semiconductor device. Some such defects (e.g., unlanded vias, electrical shorts, electrical opens, etc.) may reduce functionality of the semiconductor device and/or may render the device inoperable. Defect metrology and/or inspection techniques, such as voltage contrast (VC) inspection, are commonly implemented during one or more stages of the fabrication process to detect the presence of defects in a semiconductor device.

### BRIEF DESCRIPTION OF THE DRAWINGS

FIG. 1 illustrates an example test device implementing an example virtual ground layer in accordance with teachings of this disclosure.

FIG. 2 illustrates an example implementation of the example virtual ground layer of FIG. 1.

FIG. 3 illustrates the example test device of FIG. 1 including an example defect.

FIG. 4 illustrates a second example test device including the example virtual ground layer of FIGS. 1, 2, and/or 3.

FIG. 5 illustrates the second example test device of FIG. 4 including an example shorting defect.

FIG. 6A is a top down view of a first portion of the second example test device of FIGS. 4 and/or 5 without any shorting defects present.

FIG. 6B is a top down view of a second portion of the second example test device of FIG. 4 and/or 5 with shorting defects present.

FIG. 7 is a flowchart representative of an example method of performing voltage contrast defect inspection of the example test device of FIGS. 1 and/or 3 and/or the second example test device of FIGS. 4 and/or 5.

FIG. 8 is a flowchart representative of an example method of manufacturing the example test device of FIGS. 1 and/or 3 and/or the second example test device of FIGS. 4 and/or 5.

FIG. 9 is a flowchart representative of an example method of manufacturing the example virtual ground layer of FIGS. 1, 2, 3, 4, and/or 5.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Semiconductor devices such as integrated circuit (IC) chips and/or semiconductor dies are routinely connected to larger circuit boards (e.g., motherboards and other types of printed circuit boards (PCBs)) by a package substrate. To manufacture a semiconductor device, various fabrication processes may be used. Some such fabrication processes may produce defects (e.g., process failures) at or below a surface of a completed semiconductor device. For instance, defects such as electrical shorts, electrical opens, and/or unlanded vias can impact electrical performance of the device, rendering the device inoperable in some cases.

Typically, one or more metrology and/or inspection techniques may be implemented during and/or after a fabrication process to evaluate whether a completed semiconductor device satisfies expected performance metrics. For instance, some such techniques may be used to detect a number of defects and/or types of defects in one or more process layers of the semiconductor device, where the number and/or types of defects may be evaluated based on one or more thresholds to determine whether performance metrics of the device are satisfied. In some instances, detection of defects at earlier stages of fabrication enables issues to be addressed and/or corrected before later stages of fabrication are performed and, as a result, can reduce waste and/or inefficiency associated with the later stages of fabrication.

As technology advances and sizes of semiconductor devices and/or integrated circuitry continue to shrink, sizes of defects may similarly shrink and, as a result, may be more difficult to detect using traditional detection techniques. For instance, while optical inspection techniques (e.g., optical scans) may be used to detect electrical shorts and/or other surface-level defects of a semiconductor device, optical inspection techniques are typically incapable of detecting buried defects (e.g., unlanded vias) that are below a surface of the device. Additionally, optical inspection techniques may be unable to detect defects below a threshold size (e.g., 5 nanometers (nm) or less).

In recent years, alternative defect detection techniques, such as voltage contrast (VC) inspection (e.g., VC electron beam inspection), have been developed to facilitate detection of defects having a relatively small size (e.g., 5 nm or less) and/or that are below a surface of (e.g., buried in, embedded in) a semiconductor device. VC inspection of a semiconductor device involves utilizing a scanning electron microscope (SEM) to direct an electron beam (e.g., an e-beam) toward the device, then detecting the electrons reflected and/or bounced back from the device to generate an image (e.g., a voltage contrast image). In some cases, relatively lighter and/or darker regions of the image can be indicative of location(s) and/or type(s) of defects in the device. In some instances, based on the location(s) and/or type(s) of defects detected, one or more parameters of a fabrication process may be adjusted to reduce the presence of such defects in a completed semiconductor device.

While VC inspection can provide increased sensitivity to defects (e.g., can be used to detect defects having a size of 5 nm or less), VC inspection may necessitate significantly longer testing durations compared to other defect detection techniques (e.g., optical inspection techniques). As a result, VC inspection is typically used to examine only a portion of a semiconductor device for which optical inspection techniques are insufficient (e.g., for which expected defects have a size of 5 nm or less). For instance, a test device (e.g., a test chip, a development vehicle, a short-flow back end of line (BEOL) vehicle, a quick turn monitor (QTM) vehicle) can be used to perform VC inspection. As used herein, a “test device” means a device fabricated to mimic (e.g., emulate, replicate) a portion of interest of a semiconductor device (e.g., a completed semiconductor device). In particular, the test device mimicking (e.g., emulating, replicating) the portion of interest of the semiconductor device means that the test device includes at least some of the same structures included in the semiconductor device and/or is fabricated using at least some of the same processes used for the semiconductor device, but omits one or more other structures included in and/or one or more other processes used for the semiconductor device. For instance, when the test device is to be used to test and/or investigate BEOL structures of the semiconductor device, the test device may omit front end of line (FEOL) structures and/or processes of the semiconductor device. As used herein, a “completed semiconductor device” (e.g., a full-flow semiconductor device, a finished semiconductor device) refers to a device including a portion of (e.g., all) circuitry components (e.g., metal layers, conductive vias, transistors, etc.) necessary to perform a desired electrical function and/or task.

In some instances, one or more process layers of a test device can be examined using VC inspection, and results of the inspection can be used to update and/or adjust a fabrication process for a corresponding full-flow semiconductor device (e.g., a completed semiconductor device). However, the process layer(s) of such test devices are typically manufactured to be electrically isolated from a substrate (e.g., a silicon substrate, a grounded substrate) of the test devices and, as a result, VC inspection may not be viable. In particular, VC inspection relies on a ground (e.g., an electrical ground) to provide an electrical ground path for the process layer(s) of the test device. When such an electrical ground path is not available (e.g., as a result of the process layer(s) being electrically isolated from the grounded substrate), VC inspection results in images that contain unusable and/or meaningless information and, thus, cannot be used for accurate detection of defects in the test device.

Examples disclosed herein enable the use of VC inspection techniques on an example test device by implementing an example virtual ground layer (e.g., a conductive layer, a capacitive ground layer) in the test device. For example, the virtual ground layer can be positioned between an example substrate (e.g., a semiconductor wafer) and one or more example process layers of the test device, where the virtual ground layer is electrically isolated from (e.g., is not electrically coupled to) the substrate. As used herein, a virtual ground layer is a layer that serves as a virtual ground, which is a node in a circuit that is substantially maintained at a steady reference potential (e.g., ground voltage or zero voltage) without being directly connected (e.g., is electrically isolated) from the reference (e.g., ground) potential. In some examples, the virtual ground properties of the virtual ground layer are achieved by the size (e.g., area and thickness) of the layer being relatively large to function as an electrical sink that approximates an infinite sink for the one or more process layers containing the circuitry components to be analyzed using VC inspection of the test device (e.g., to enable detection of defects on and/or within one(s) of the process layers). In some examples, the virtual ground layer includes a metal layer, an amorphous silicon layer, and an adhesive layer coupled between the metal layer and the amorphous silicon layer. In some examples, the adhesive layer includes titanium and nitrogen, and the metal layer includes at least one of tungsten, cobalt, molybdenum, or aluminum.

In some examples, an example alignment mark layer is coupled to a surface of the substrate (e.g., between the substrate and the virtual ground layer) to enable patterning and/or positioning of the one or more process layers with respect to the substrate. In some examples, the alignment mark layer can be coupled to and/or provided on the virtual ground layer. In some examples, a dielectric layer (e.g., a silicon dioxide layer) is provided on and/or around the alignment mark layer to provide a substantially flat surface on which the virtual ground layer and/or the one or more process layers can be provided. In some examples, the dielectric layer is a transparent material, and the virtual ground layer has a thickness of 20 nanometers (nm) or less such that the alignment mark layer is visible through the dielectric layer and/or the virtual ground layer.

By providing a virtual ground layer to electrically couple to one(s) of the process layers, examples disclosed herein function as an electrical sink for one or more conductive features (e.g., vias, traces, conductive lines, contact pads, etc.) included in the process layers. In some such examples, when a scanning electron microscopy (SEM) tool emits and/or directs an example electron beam toward the test device (e.g., to enable VC inspection of the process layers), the virtual ground layer provides a replenishing supply of electrons for one(s) of the conductive features electrically coupled to the virtual ground layer. As a result, the one(s) of the conductive features remain electrically neutral (e.g., are not positively charged) when exposed to the electron beam. In such examples, electrons from the electron beam can be deflected from the electrically-neutral conductive feature(s) and detected by the SEM tool to generate an example image (e.g., a voltage contrast (VC) image) corresponding to the test device. In some examples, the image can be used to facilitate detection of defects (e.g., unlanded vias, electrical opens and/or shorts, etc.) that are undetectable or not easily detectable using optical detection methods. For example, the image can enlarge (e.g., magnify) the appearance of defects and/or can indicate the presence of defects below a surface of the test device.

Advantageously, by providing a virtual ground layer in an example test device, examples disclosed herein enable VC inspection to be performed on one or more process layers of the test device. As a result, examples disclosed herein enable detection of defects having a relatively small size (e.g., 5 nanometers or less), defects that are located below a surface of the test device, and/or defects that are otherwise difficult to detect using other defect inspection techniques (e.g., optical inspection techniques). Further, by enabling VC inspection to be performed on short-flow vehicles and/or devices (e.g., test devices that do not provide full functionality of a completed semiconductor device), examples disclosed herein enable errors in a fabrication process flow to be identified and/or corrected prior to fabrication of a corresponding full-flow semiconductor device, thus reducing time and/or material waste associated with correction and/or re-fabrication of the semiconductor device.

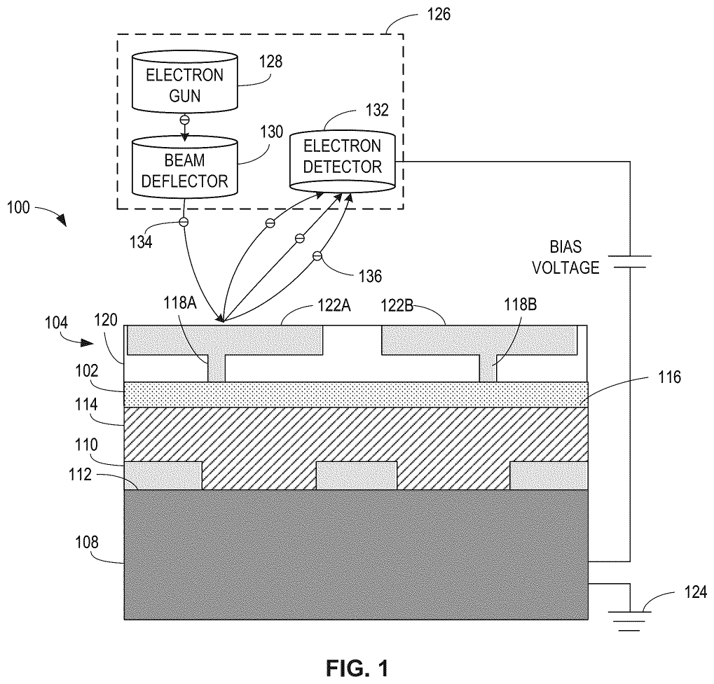

FIG. 1 illustrates an example test device (e.g., a test chip, a short-flow back end of line (BEOL) vehicle) 100 including an example virtual ground layer (e.g., a conductive layer, a capacitive ground layer) 102 constructed in accordance with teachings of this disclosure. In some examples, the test device 100 is fabricated to substantially mimic (e.g., emulate, replicate) a portion of a full-flow (e.g., completed) semiconductor device (e.g., a semiconductor die, an IC chip), but does not enable full electrical functionality of the completed semiconductor device. For example, the test device 100 of FIG. 1 does not include transistors and/or other circuitry components (e.g., FEOL layers) in and/or below example process layers (e.g., back end (e.g., BEOL) layers) 104 of the test device 100. Instead, the test device 100 can be used to test and/or evaluate one or more stages of a process flow used for fabricating one(s) of the process layers 104, and the results of such testing can be used to adjust and/or correct the process flow for the full-flow semiconductor device to satisfy given design and/or performance metrics. For example, the performance metrics can be related to a threshold number of defects, location(s) of the defects, type(s) of the defects, etc.

In the illustrated example of FIG. 1, the test device 100 includes an example substrate (e.g., a wafer, a semiconductor wafer) 108. In this example, the substrate 108 includes silicon. In some examples, the substrate can include one or more different materials (e.g., organic and/or inorganic materials) in addition to or instead of silicon. In this example, an example alignment mark layer 110 is coupled to a first surface 112 of the substrate 108. In some examples, the alignment mark layer 110 can be used for positioning and/or aligning one or more features (e.g., conductive feature(s)) of the process layers 104 with respect to the underlying substrate 108. For example, the process layers 104 can be structured according to metal interconnects for an integrated circuit. In some examples, the conductive feature(s) can include one or more conductive vias, conductive lines, traces, wires, grounded lines, etc.

In some examples, the alignment mark layer 110 is provided on the substrate 108 by providing (e.g., laminating, depositing) a material layer (e.g., a titanium nitride layer) on the first surface 112 of the substrate 108, then removing (e.g., etching) one or more portions of the material layer to pattern and/or produce the alignment mark layer 110. While the alignment mark layer 110 is below the virtual ground layer 102 in this example, the alignment mark layer 110 can be positioned above (e.g., on) the virtual ground layer 102 in some examples. In some examples, an example dielectric layer 114 is provided on (e.g., surrounds, encases) the alignment mark layer 110. In this example, the dielectric layer 114 includes a substantially transparent material (e.g., silicon dioxide) that enables the alignment mark layer 110 to be visible through the dielectric layer 114. Further, the dielectric layer 114 provides a second example surface 116 that is substantially flat and on which the virtual ground layer 102 and/or the process layer(s) 104 can be provided.

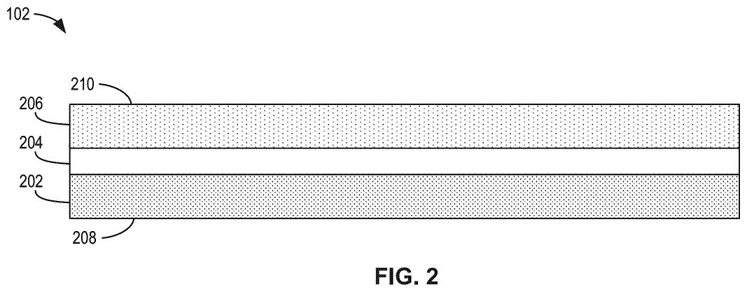

In the illustrated example of FIG. 1, the virtual ground layer 102 is provided (e.g., deposited, laminated) on the second surface 116 of the dielectric layer 114. For example, the virtual ground layer 102 extends continuously across an area corresponding to a footprint (or a majority of the footprint) of the substrate 108 (e.g., corresponding to an area of the first surface 112 of the substrate 108). In some examples, the virtual ground layer 102 extends continuously across (e.g., and/or beyond) an area associated with one or more example chips (e.g., IC chips) to be implemented as test devices on the substrate 108. That is, as noted above, in some examples, the substrate 108 is a semiconductor (e.g., silicon) wafer and the virtual ground layer 102 extends continuously across most if not all of the wafer. In some examples, the virtual ground layer 102 can include one or more example material layers provided on the second surface 116. For example, FIG. 2 illustrates an example implementation of the example virtual ground layer 102 of FIG. 1. In the illustrated example of FIG. 2, the virtual ground layer 102 includes a first example layer 202, a second example layer 204 coupled to the first layer 202, and a third example layer 206 coupled to the second layer 204. In this example, a third example surface 208 of the virtual ground layer 102 is to face the substrate 108 of FIG. 1, and a fourth example surface 210 of the virtual ground layer 102 (e.g., opposite the third surface 208) is to face away from the substrate 108 (e.g., toward the process layer(s) 104 of FIG. 1). As such, the first layer 202 is closer to the substrate 108 than the second and third layers 204, 206, and the second layer 204 is closer to the substrate 108 than the third layer 206 (e.g., the third layer 206 is farther from the substrate 108 than the first and second layers 202, 204, and the second layer 204 is farther from the substrate 108 than the first layer 202).

In the example of FIG. 2, the first layer 202 includes silicon, and the third layer 206 is a metal layer including at least one of tungsten, cobalt, molybdenum, or aluminum. In some examples, the silicon in the first layer 202 has an amorphous crystal structure. In some examples, amorphous silicon is selected for the first layer 202 such that the first layer 202 is electrically conductive while providing greater transmittance of visible light compared to the metal layer (e.g., the third layer 206). Conversely, a metal material (e.g., tungsten, cobalt, molybdenum, aluminum, etc.) is utilized for the third layer 206 to provide increased electrical conductivity compared to the first layer 202. The increased electrical conductivity of the third layer 206 increases the ability of the virtual ground layer 102 to function as a virtual ground (e.g., as an electrical sink) for the process layers 104. In some examples, a thickness of the virtual ground layer 102 (e.g., between the third and fourth surfaces 208, 210) is 20 nanometers (nm) or less, which enables the alignment mark layer 110 of FIG. 1 to be visible through the virtual ground layer 102. In some examples, the first layer 202 has a first thickness, the second layer 204 has a second thickness, and the third layer 206 has a third thickness, where each of the first thickness, the second thickness, and the third thickness can be between 10 nm and 100 nm.

In the example of FIG. 2, the second layer 204 is an adhesive layer that reduces and/or prevents delamination between the first and third layers 202, 206. In some examples, the second layer 204 includes titanium nitride. In some examples, one or more different materials can be used for one(s) of the layers 202, 204, 206. For example, the material(s) for the one(s) of the layers 202, 204, 206 can be selected such that the first layer 202 has a first electrical resistance, the second layer 204 has a second electrical resistance (e.g., less than the first electrical resistance), and the third layer 206 has a third electrical resistance (e.g., less than the first electrical resistance and the second electrical resistance). In some examples, the second layer 204 can be omitted. In some examples, the both the first and second layers 202, 204 can be omitted. In some examples, the virtual ground layer 102 includes one or more additional layers beyond the three layers 202, 204, 206 shown in FIG. 2.

Returning to FIG. 1, one(s) of the process layers 104 are provided (e.g., fabricated, deposited, laminated) on the virtual ground layer 102. For example, the process layer(s) 104 can be provided by providing alternating layers of conductive material (e.g., metallization layer(s)) and dielectric material on the virtual ground layer 102. In FIG. 1, only one dielectric layer (e.g., including example dielectric material 120) and one conductive layer (e.g., including two example metal pads 122A, 122B) are shown. However, the process layer(s) 104 can include any suitable number of dielectric layers and/or conductive layers (e.g., metallization layer(s)). In some examples, the metallization layer(s) are structured according to an interconnect design for a semiconductor device (e.g., a full-flow semiconductor device), a portion of which the test device 100 of FIG. 1 is intended to emulate (e.g., mimic, replicate). In some examples, the process layer(s) 104 can be provided by providing dielectric material on the virtual ground layer 102, removing portion(s) of the dielectric material to provide opening(s) (e.g., vias) in the dielectric material, and providing a second material (e.g., a conductive material(s)) in the opening(s). In the illustrated example of FIG. 1, the process layer(s) 104 include first and second conductive vias (e.g., metal vias, metal interconnects, conductive features) 118A, 118B extending through the example dielectric material 120 and electrically coupled to the virtual ground layer 102. Further, the process layer(s) 104 include the example pads (e.g., metal interconnects, contact pads) 122A, 122B coupled to respective ones of the conductive vias 118A, 118B. While two of the conductive vias 118A, 118B and two of the pads 122A, 122B are shown in this example, a different number of the conductive vias 118A, 118B and/or the pads 122A, 122B may be used instead (e.g., less than two, three or more).

In the illustrated example of FIG. 1, the substrate 108 is electrically coupled to an example ground (e.g., an electrical ground) 124, and the dielectric layer 114 electrically isolates the virtual ground layer 102 from the substrate 108 and/or the ground 124 (e.g., the virtual ground layer 102 is not electrically coupled to the substrate 108 and/or the ground 124). In some examples, the virtual ground layer 102 enables VC inspection to be performed on the example test device 100. For example, VC inspection can be performed using an example scanning electron microscopy (SEM) tool 126, where the SEM tool 126 includes an example electron gun 128, an example beam deflector 130, and an example electron detector 132.

In the example of FIG. 1, to perform VC inspection of the test device 100, the electron gun 128 generates and/or outputs an example electron beam 134, and the beam deflector 130 deflects and/or directs the electron beam 134 toward one or more locations of the test device 100. In this example, the electron beam 134 is directed toward the first pad 122A and/or the first conductive via 118A to detect whether there is a defect associated with the first pad 122A and/or the first conductive via 118A (e.g., whether the first conductive via 118A, intended to be landed based on the interconnect design of the full-flow semiconductor device, is unlanded and/or is otherwise not electrically coupled to the virtual ground layer 102). In some examples, as a result of irradiating the test device 100 (e.g., emitting the electron beam 134 toward the test device 100), two types of electrons can be observed. For example, backscattered electrons penetrate into the test device 100, and secondary electrons 136 (e.g., having relatively lower energy compared to the backscattered electrons) bounce back and/or are deflected from the test device 100.

In some examples, the electron detector 132 detects the secondary electrons 136 that are deflected (e.g., emitted) from the test device 100, and the SEM tool 126 can generate and/or output an example image (e.g., a VC image) based on the detected secondary electrons 136. In some examples, a brightness of the image at one or more pixels (e.g., contrast of the brightness of the pixels relative to other regions of the image) can be representative of whether a defect is present at one or more respective locations of the test device 100. For example, one(s) of the pixels corresponding to the first conductive via 118A may appear relatively dark (e.g., relative to other pixels in the image) when the first conductive via 118A is unlanded (e.g., is not electrically coupled to the virtual ground layer 102). Alternatively, the one(s) of the pixels corresponding to the first conductive via 118A may appear relatively bright (e.g., relative to the other pixels in the image) when the first conductive via 118A is landed (e.g., is electrically coupled to the virtual ground layer 102). In some examples, the brightness of the image at one or more pixels is based on the number of deflected electrons 136 detected by the electron detector 132 from one or more locations of the test device 100 (e.g., where the location(s) of the test device 100 are represented by respective pixel(s) in the image).

In the illustrated example of FIG. 1, the first conductive via 118A is landed (e.g., is electrically coupled between the first pad 122A and the virtual ground layer 102). In such examples, the virtual ground layer 102 provides an electrical sink for the first conductive via 118A and/or the first pad 122A. In this example, the SEM tool 126 is electrically coupled to the substrate 108 to provide a bias voltage to the substrate 108 (e.g., to extract electrons from the substrate 108). In some examples, when the SEM tool 126 directs and/or emits the electron beam 134 toward the first pad 122A, the virtual ground layer 102 enables the first pad 122A to remain electrically neutral (e.g., not positively or negatively charged). For example, because the first conductive via 118A electrically couples the first pad 122A to the virtual ground layer 102, the virtual ground layer 102 can provide a replenishing supply of electrons (e.g., secondary electrons) to the first pad 122A. As a result, the first pad 122A does not become positively charged responsive to the electron beam 134 being emitted toward the first contact 112A.

In the illustrated example of FIG. 1, because the first pad 122A is electrically neutral, a portion (e.g., all, most, some) of the secondary electrons 136 from the electron beam 134 are deflected from the first pad 122A and toward the electron detector 132. In some examples, the electron detector 132 selects a brightness of pixel(s) in a voltage contrast (VC) image corresponding to the test device 100 based on a number of the secondary electrons 136 detected from the first pad 122A (e.g., relative to the number of secondary electrons 136 detected from other location(s) of the test device 100). For example, the pixels in the VC contrast image correspond to respective different locations of the test device 100, and the brightness of respective ones of the pixels is based on the number of electrons detected from the corresponding locations (e.g., relative to other location(s) of the test device 100). In some examples, when at least a threshold number of the secondary electrons 136 are deflected from the first pad 122A (e.g., compared to other location(s) of the test device 100), the pixel(s) corresponding to the first pad 122A and/or the first conductive via 118A in the VC image are relatively bright (e.g., compared to other pixel(s) in the image). In such examples, the VC image indicates that the first conductive via 118A extends from the first pad 122A to the virtual ground layer 102 (e.g., the first conductive via 118A is landed) and, thus, that no defect is present.

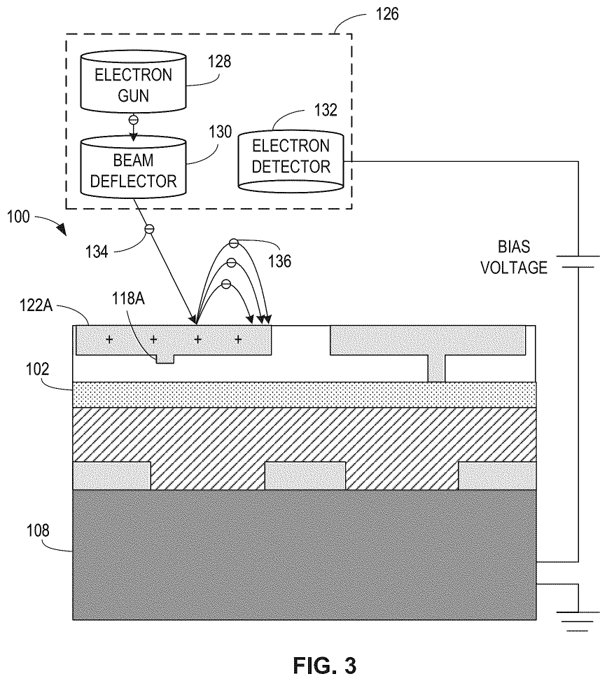

FIG. 3 illustrates the example test device 100 of FIG. 1 including an example defect. For example, the defect in FIG. 3 corresponds to the first conductive via 118A being unlanded (e.g., not electrically coupled to the virtual ground layer 102) when the first conductive via 118A is intended to be landed and/or is intended to be electrically coupled to one or more metallization layers (e.g., based on an interconnect design of a portion of a semiconductor device which the test device 100 is intended to emulate). In the illustrated example of FIG. 3, when the SEM tool 126 directs and/or emits the electron beam 134 (e.g., from the electron gun 128 and/or the beam deflector 130) toward the first pad 122A, the first pad 122A becomes electrically charged (e.g., positively charged if the number of secondary electrons 136 leaving the first pad 122A exceeds the number of electrons in the electron beam 134 emitted into the first pad 122A). For example, because the first conductive via 118A is unlanded (e.g., does not extend to the virtual ground layer 102), the virtual ground layer 102 does not provide a replenishing supply of electrons (e.g., secondary electrons) to the first pad 122A. As a result, the first pad 122A becomes positively charged responsive to the electron beam 134 being emitted toward the first contact 112A.

In the illustrated example of FIG. 3, because the first pad 122A is positively charged, the first pad 122A suppresses deflection and/or emission of the secondary electrons 136 from the electron beam 134. For example, ones of the secondary electrons 136 are drawn (e.g., pulled) toward the first pad 122A as a result of the positive charge at the first pad 122A, such that relatively few of the secondary electrons 136 reach and/or are detected by the electron detector 132. In some examples, when the electron detector 132 detects relatively fewer (e.g., less than a threshold number and/or ratio) of the secondary electrons 136 from the first pad 122A (e.g., relative to other location(s) of the test device 100), the pixel(s) corresponding to the first pad 122A and/or the first conductive via 118A (e.g., in an example VC image corresponding to the test device 100) are relatively dark (e.g., compared to other pixel(s) in the image). In such examples, the VC image indicates that the first conductive via 118A does not extend to the virtual ground layer 102 (e.g., the first conductive via 118A is unlanded) and, thus, indicates that a defect is present in the test device 100.

While FIG. 3 illustrates a first example type of defect (e.g., an unlanded via, a buried defect) that may be identified in the test device 100 using VC inspection, one or more different types of defects (e.g., an electrical short, a side-to-side (STS) short, an end-to-end (ETE) short, etc.) may be identified in the test device 100 by implementing the virtual ground layer 102 of FIGS. 1, 2, and/or 3.

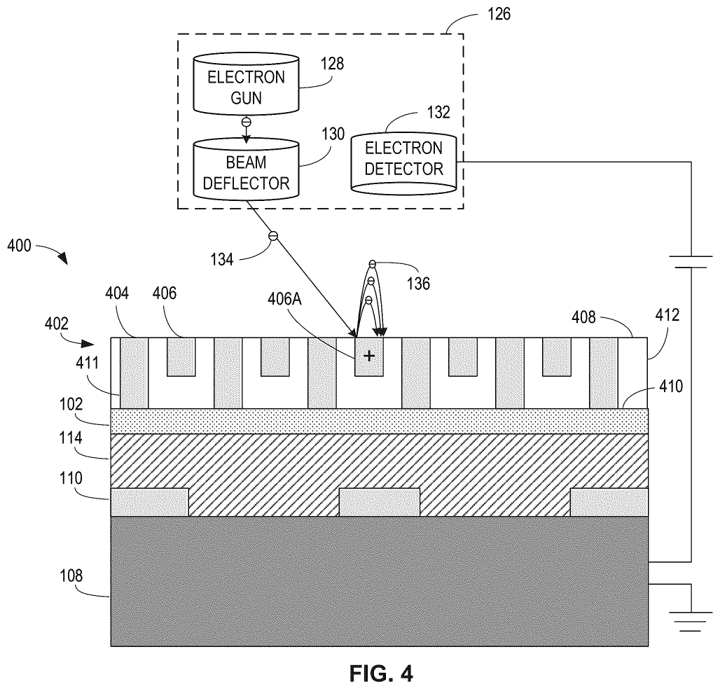

FIG. 4 illustrates a second example test device 400 including the example virtual ground layer 102 of FIGS. 1, 2 and/or 3. In the illustrated example of FIG. 4, the second test device 400 is similar to the test device 100 of FIGS. 1 and/or 3 (e.g., including the substrate 108, the alignment mark layer 110, and the dielectric layer 114 of the test device 100 of FIGS. 1 and/or 3), but includes second example process layers 402 (e.g., instead of the process layers 104 of FIGS. 1 and/or 3) coupled to the virtual ground layer 102. In the illustrated example of FIG. 4, the second process layers 402 include first example conductive features (e.g., first conductive lines, first conductive wires, grounded lines) 404 and second example conductive features (e.g., second conductive lines, second conductive wires, floating lines) 406 positioned between respective pairs of the first conductive lines 404. In this example, the first and second conductive features 404, 406 are conductive lines or wires extending into and out of the drawing shown in FIG. 4. As shown in the illustrated example of FIG. 4, the first conductive lines 404 and the second conductive lines 406 are fabricated to extend from a first surface 408 of the second process layers 402 into example dielectric material 412 of the second process layers 402. In this example, example vias (e.g., conductive vias) 411 extend between a second surface 410 of the virtual ground layer 102 and respective ones of the first conductive lines 404, such that the first conductive lines 404 are electrically coupled to the virtual ground layer 102. By contrast, in this example, the second conductive lines 406 are not electrically coupled to the virtual ground layer 102. That is, the second conductive lines 406 are floating lines. Further, the dielectric material 412 electrically isolates the second conductive lines 406 from the first conductive lines 404 in the second process layers 402.

In the illustrated example of FIG. 4, a second type of defect (e.g., an electrical short, an STS short) may be present in the second test device 400 when one(s) of the second conductive lines 406 are inadvertently coupled to one(s) of the first conductive lines 404 (e.g., as a result of error in one or more stages of fabrication of the second test device 400). In some examples, a size of an electrical short between ones of the conductive lines 404, 406 may be relatively small (e.g., 5 nanometers or less), such that the electrical short may be undetectable using some known inspection techniques (e.g., optical inspection techniques). In some examples, the SEM tool 126 can be used to perform VC inspection of the second test device 400 to detect whether electrical shorting defects are present in the second test device 400 in accordance with teachings disclosed herein.

In the illustrated example of FIG. 4, to perform VC inspection of the second test device 400, the SEM tool 126 directs and/or emits the electron beam 134 (e.g., from the electron gun 128 and/or the beam deflector 130) toward a first one of the second conductive lines 406A. As a result, the first one of the second conductive lines 406A becomes electrically charged (e.g., positively charged). For example, because the first one of the second conductive lines 406A is not coupled to one(s) of the first conductive lines 404 (and, as a result, is not electrically coupled to the virtual ground layer 102), the virtual ground layer 102 does not provide a replenishing supply of electrons (e.g., secondary electrons) to the first one of the second conductive lines 406A. As a result, assuming the number of secondary electrons 136 leaving exceeds the number of electrons in the electron beam 134 being introduced, the first one of the second conductive lines 406A becomes positively charged responsive to the electron beam 134 being emitted toward the first one of the second conductive lines 406A.

In this example, because the first one of the second conductive lines 406A is positively charged, the first one of the second conductive lines 406A suppresses deflection and/or emission of the secondary electrons 136 from the electron beam 134. For example, ones of the secondary electrons 136 are drawn (e.g., pulled) toward the first one of the second conductive lines 406A as a result of the positive charge at the first one of the second conductive lines 406A, such that relatively few of the secondary electrons 136 reach and/or are detected by the electron detector 132. In some examples, when the electron detector 132 detects less than a threshold number of the secondary electrons 136 from the first one of the second conductive lines 406A (e.g., relative to other location(s) of the second test device 400), the pixel(s) corresponding to the first one of the second conductive lines 406A (e.g., in an example VC image corresponding to the second test device 400) are relatively dark (e.g., compared to other pixel(s) in the VC image). In such examples, the VC image indicates that the first one of the second conductive lines 406A is not coupled to one(s) of the first conductive lines 404 and, thus, indicates that there is no shorting defect corresponding to the first one of the second conductive lines 406A.

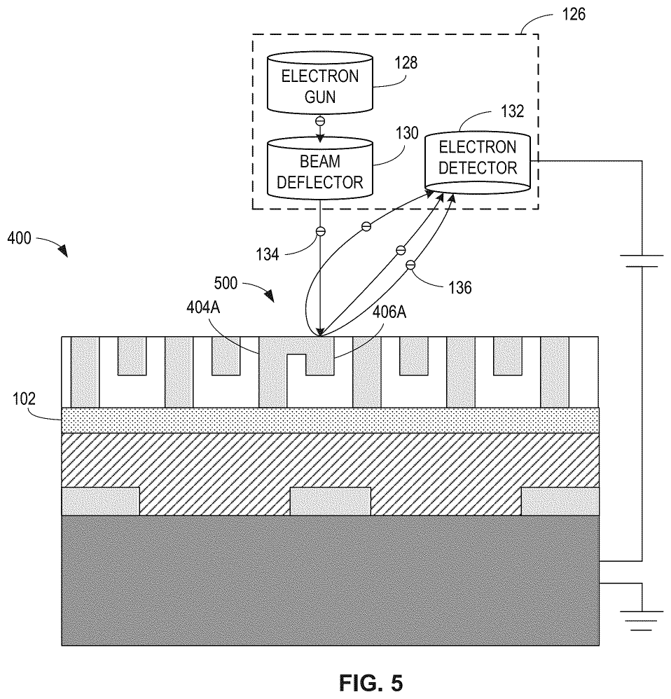

FIG. 5 illustrates the second example test device 400 of FIG. 4 including an example shorting defect (e.g., an electrical short, a side-to-side (STS) short) 500. In the illustrated example of FIG. 5, the shorting defect 500 is present between the first one of the second conductive lines 406A and a first one of the first conductive lines 404A (e.g., the first one of the second conductive lines 406A is coupled to the first one of the first conductive lines 404A). In such examples, the first one of the second conductive lines 406A is electrically coupled to the virtual ground layer 102 (e.g., through the shorting defect 500 and the first one of the first conductive lines 404A), such that the virtual ground layer 102 provides an electrical sink for the first one of the second conductive lines 406A and the shorting defect 500.

In the illustrated example of FIG. 5, the SEM tool 126 is used to perform VC inspection of the second test device 400 to detect the shorting defect 500. In this example, when the SEM tool 126 directs and/or emits the electron beam 134 toward the first one of the second conductive lines 406A, the virtual ground layer 102 enables the first one of the second conductive lines 406A and the shorting defect 500 to remain electrically neutral (e.g., not positively or negatively charged). For example, because the first one of the first conductive lines 404A electrically couples the first one of the second conductive lines 406A and/or the shorting defect 500 to the virtual ground layer 102, the virtual ground layer 102 can provide a replenishing supply of electrons (e.g., secondary electrons) to the first one of the second conductive lines 406A and/or the shorting defect 500. As a result, the first one of the second conductive lines 406A and the shorting defect 500 do not become positively charged responsive to the electron beam 134 being emitted toward the first one of the second conductive lines 406A and/or the shorting defect 500.

In the illustrated example of FIG. 5, because the first one of the second conductive lines 406A and the shorting defect 500 are electrically neutral, ones of the secondary electrons 136 from the electron beam 134 are deflected from the first one of the second conductive lines 406A and/or the shorting defect 500 and toward the electron detector 132. In some examples, the electron detector 132 selects a brightness of pixel(s) in a voltage contrast (VC) image (e.g., corresponding to the second test device 400) based on a number of the secondary electrons 136 detected. For example, when at least a threshold number of the secondary electrons 136 are deflected from the shorting defect 500 and/or the first one of the second conductive lines 406A, the pixel(s) corresponding to the shorting defect 500 and/or the first one of the second conductive lines 406A in the VC image are relatively bright (e.g., compared to other pixel(s) in the VC image). As a result, the VC image illustrates and/or represents the shorting defect 500 between the first one of the second conductive lines 406A and the first one of the first conductive lines 404A.

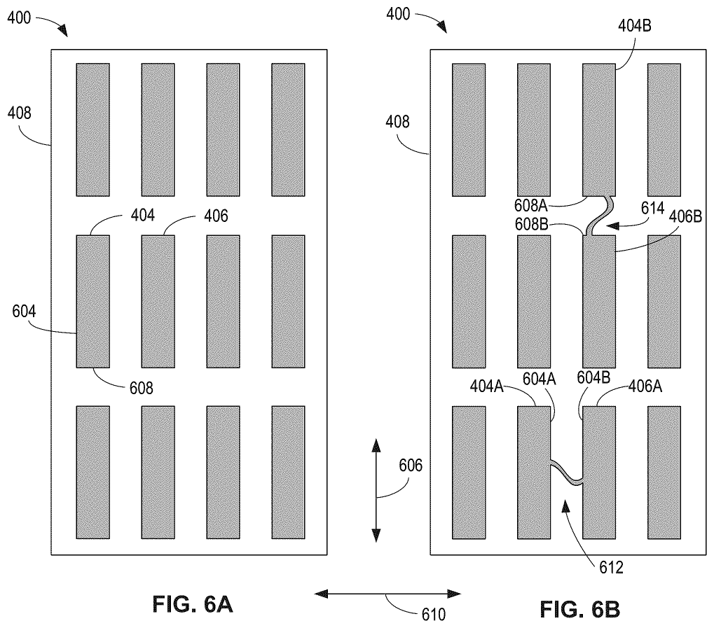

FIG. 6A is a top down view of a first portion of the second example test device of FIGS. 4 and/or 5 without any shorting defects present. In the illustrated example of FIG. 6A, the first surface 408 of the test device 400 includes the example conductive lines 404, 406 of FIGS. 4 and/or 5 arranged in a grid-like manner. In this example, the conductive lines 404, 406 have a rectangular shape, where respective example sides 604 of the conductive lines 404, 406 are oriented along a first example direction 606 and respective example ends 608 of the conductive lines 404, 406 are oriented along a second example direction 610 (e.g., perpendicular to the first direction 606). In this example, a first length of the sides 604 is greater than a second length of the ends 608. In some examples, a shape and/or arrangement of the conductive lines 404, 406 may be different. In the illustrated example of FIG. 6A, there are no electrical connections (e.g., shorts) between ones of the conductive lines 404, 406 along the first surface 408.

FIG. 6B is a top down view of a second portion of the second example test device of FIG. 4 and/or 5 with example shorting defects (e.g., electrical shorts) 612, 614 present. In the illustrated example of FIG. 6B, a first example shorting defect 612 is present between (e.g., electrically couples) first ones of the first and second conductive lines 404A, 406B, and a second example shorting defect 614 is present between (e.g., electrically couples) second ones of the first and second conductive lines 404B, 406B40. In some examples, the first shorting defect 612 is representative of the example shorting defect 500 shown in FIG. 5. In the example of FIG. 6B, the first shorting defect 612 is a side-to-side (STS) short in which respective sides 604A, 604B of the first ones of the first and second conductive lines 404A, 406A are coupled by the first shorting defect 612. Conversely, the second shorting defect 614 is an end-to-end (ETE) short in which respective ends 608A, 608B of the second ones of the first and second conductive lines 404B, 406B are coupled by the second shorting defect 614. In some examples, an STS short may occur as a result of sidewalls between sides 604 of the conductive lines 404, 406 breaking down (e.g., along the second direction 610). In some examples, an ETE short may occur as a result of plug and/or line break fails between ones of the conductive lines 404, 406 (e.g., along the first direction 606). In some examples, sizes (e.g., length(s) and/or width(s)) of the first and second shorting defects 612, 614 are relatively small (e.g., less than 5 nanometers) and, as a result, are undetectable using optical inspection techniques. Instead, in some examples, the first and second shorting defects 612, 614 can be detected using VC inspection of the second test device 400 in accordance with teachings disclosed herein.

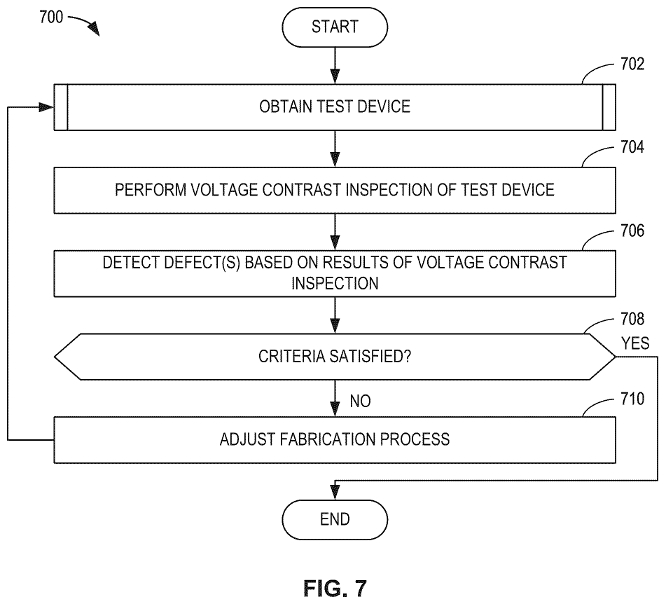

FIG. 7 is a flowchart representative of an example method 700 of performing voltage contrast defect inspection of the example test device 100 of FIGS. 1 and/or 3 and/or the second example test device 400 of FIGS. 4 and/or 5 including the example virtual ground layer 102 of FIGS. 1, 2, 3, 4, and/or 5. In some examples, some or all of the operations outlined in the example method 700 are performed automatically by fabrication equipment that is programmed to perform the operations. Although the example method of manufacturing is described with reference to the flowchart illustrated in FIG. 7, many other methods may alternatively be used. For example, the order or execution of the blocks may be changed, and/or some of the blocks described may be combined, divided, re-arranged, omitted, eliminated, and/or implemented in any other way.

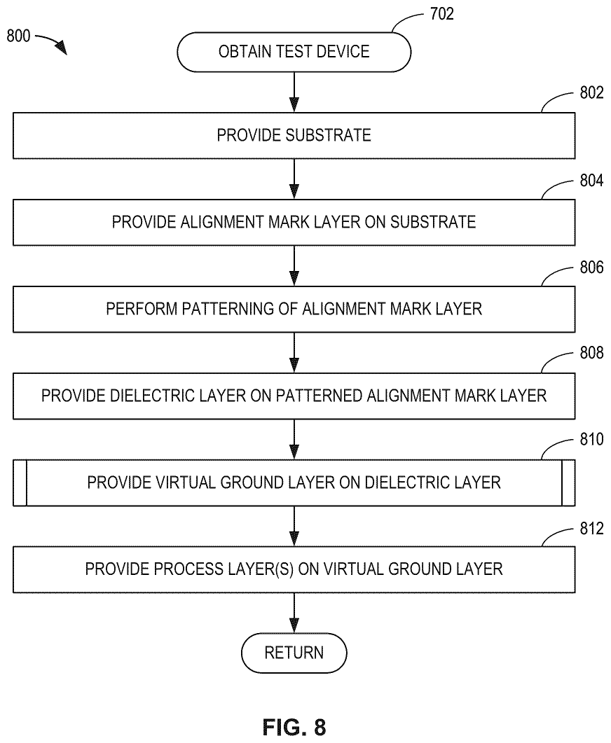

The example method 700 begins at block 702 by obtaining an example test device (e.g., the test device 100 of FIGS. 1 and/or 3 and/or the second test device 400 of FIGS. 4, 5, 6A, and/or 6B). In some examples, the test device 100 and/or the second test device 400 can be obtained by executing an example method of manufacturing described below in connection with FIG. 8. In some examples, the test device 100 and/or the second test device 400 can be manufactured separately (e.g., by a third party) and can be obtained as a completed test device 100, 400 from the third party. In some examples, the test device 100 and/or the second test device 400 include the example virtual ground layer 102 of FIGS. 1, 2, and/or 3 to enable voltage contrast inspection of the test device 100 and/or the second test device 400.

At block 704, the example method 700 includes performing voltage contrast inspection of the test device 100 and/or the second test device 400. For example, the example SEM tool 126 of FIGS. 1 and/or 3 can be used to apply a voltage bias to the substrate 108 of the test device 100 and/or the second test device 400, and the SEM tool 126 can emit and/or direct the example electron beam 134 toward one or more locations of the test device 100 and/or the second test device 400. In some examples, the electron detector 132 of the SEM tool 126 detects one(s) of the secondary electrons 136 deflected from the test device 100 and/or the second test device 400 to generate an example voltage contrast image corresponding to the test device 100 and/or the second test device 400. In some examples, different pixel(s) of the voltage contrast image correspond to respective different location(s) of the test device 100 and/or the second test device 400 (e.g., the first pad 122A and/or the second pad 122B, the first conductive via 118A and/or the second conductive via 118B, the first conductive line(s) 404 and/or the second conductive line(s) 406, etc.), and brightness value(s) of the pixel(s) are based on a relative number of the secondary electrons 136 detected from the respective location(s).

At block 706, the example method 700 includes detecting one or more example defects in the test device 100 and/or the second test device 400 based on results of the voltage contrast inspection. For example, the voltage contrast image generated based on the voltage contrast inspection can be evaluated to determine whether one or more defects (e.g., unlanded vias, electrical opens and/or shorts, etc.) are present. In some examples, the number(s) and/or type(s) of the defect(s) can be determined by identifying relatively brighter and darker areas of the voltage contrast image to determine whether an electrical connection is present. In some examples, a first type of defect (e.g., an electrical short) is detected when an electrical connection is present between two or more locations where no electrical connection is desired, and a second type of defect (e.g., an electrical open) is detected when an electrical connection is not present between two or more locations where an electrical connection is desired. In some example, a third type of defect (e.g., an unlanded via) is detected when a via does not extend to a desired location.

At block 708, the example method 700 includes determining whether criteria associated with the test device 100 and/or the second test device 400 are satisfied. For example, the number(s) and/or type(s) of defects detected as a result of voltage contrast inspection are compared to one or more example thresholds. In some examples, the criteria are satisfied when the number of defects associated with a particular defect type satisfies (e.g., is less than or equal to) a corresponding threshold, and the criteria are not satisfied when the number of defects associated with the particular defect type does not satisfy (e.g., is greater than) the corresponding threshold. In some examples, in response to determining that the criteria are not satisfied (e.g., block 708 returns a result of NO), the process proceeds to block 710, at which the example method 700 includes adjusting an example fabrication process. For example, the fabrication process can be used to manufacture a semiconductor device corresponding to the example test device 100 and/or the second test device 400. In some examples, the fabrication process can be adjusted based on the number(s) and/or type(s) of defects detected in the test device 100 and/or the second test device 400 (e.g., to reduce defects in a completed semiconductor device). In some examples, adjusting the fabrication process can include adjusting one or more example parameters (e.g., material(s) and/or material composition(s), etching duration, thin film thickness, etc.) associated with one or more stages of the fabrication process (e.g., deposition, etching, lithography, metallization, polishing, etc.). Alternatively, in response to determining that the criteria are satisfied (e.g., block 708 returns a result of YES), the process ends.

FIG. 8 is a flowchart representative of an example method 800 of manufacturing the example test device 100 of FIGS. 1 and/or 3 and/or the second example test device 400 of FIGS. 4, 5, 6A, and/or 6B (e.g., in connection with block 702 of FIG. 7). In some examples, some or all of the operations outlined in the example method 800 are performed automatically by fabrication equipment that is programmed to perform the operations. Although the example method of manufacturing is described with reference to the flowchart illustrated in FIG. 8, many other methods may alternatively be used. For example, the order or execution of the blocks may be changed, and/or some of the blocks described may be combined, divided, re-arranged, omitted, eliminated, and/or implemented in any other way.

The example method 800 begins at block 802 by providing an example substrate (e.g., the substrate 108 of FIGS. 1, 3, 4, and/or 5). For example, the substrate 108 can be fabricated and/or obtained (e.g., from a third party). In some examples, the substrate 108 includes silicon. In some examples, the substrate 108 can include one or more different semiconductor materials (e.g., in addition to or instead of silicon).

At block 804, the example method 800 includes providing an alignment mark layer (e.g., the alignment mark layer 110 of FIGS. 1, 3, 4, and/or 5) on the substrate 108. For example, the alignment mark layer 110 can be provided on the first surface 112 of the substrate 108 by providing a material layer on the first surface 112. In some examples, the alignment mark layer 110 is optional and/or may be omitted.

At block 806, the example method 800 includes performing patterning of the alignment mark layer 110. For example, one or more portions of the alignment mark layer 110 can be removed (e.g., by etching) to provide a pattern in the alignment mark layer 110. In some examples, the pattern of the alignment mark layer 110 can be used for aligning one or more features of subsequent layers (e.g., the process layer(s) 104 and/or the second process layer(s) 402) of the test device 100 and/or the second test device 400 with respect to the substrate 108.

At block 808, the example method 800 includes providing an example dielectric layer (e.g., the dielectric layer 114 of FIG. 1) on the patterned alignment mark layer 110. For example, the dielectric layer 114 is provided on the alignment mark layer 110 by providing (e.g., depositing, laminating) example dielectric material (e.g., silicon dioxide) on the alignment mark layer 110. In some examples, the dielectric layer 114 is provided to provide a substantially flat second surface 116 on which subsequent layers (e.g., the virtual ground layer 102, the process layer(s) 104, and/or the second process layer(s) 402) can be provided.

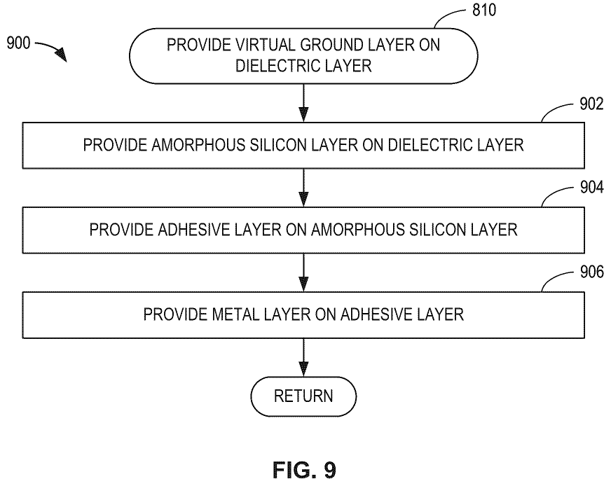

At block 810, the example method 800 includes providing an example virtual ground layer (e.g., the virtual ground layer 102 of FIGS. 1, 2, and/or 3) on the dielectric layer 114. For example, the virtual ground layer 102 is provided on the dielectric layer 114 by providing conductive material that extends continuously across an area corresponding to a footprint (or a majority of the footprint) of the substrate 108. In some examples, the virtual ground layer 102 can include at least one of a metal layer (e.g., including tungsten, cobalt, molybdenum, aluminum, etc.), an adhesive layer (e.g., including titanium nitride), or an amorphous silicon layer. In some examples, the virtual ground layer 102 can be provided based on the example method described below in connection with FIG. 9.

At block 812, the example method 800 includes providing one or more example process layers (e.g., the process layers 104 of FIGS. 1 and/or 3 and/or the second process layers 402 of FIGS. 4, 5, 6A, and/or 6B) on the virtual ground layer 102. For example, the process layers 104 and/or the second process layers 402 can be provided on the virtual ground layer 102 by providing (e.g., depositing, laminating) alternating layers of conductive material and dielectric material on the virtual ground layer 102. In some examples, the process layers 104 and/or the second process layers 402 can include one or more electrical connections (e.g., the conductive via(s) 118A, 118B, the first conductive line(s) 404 and/or the second conductive line(s) 406, traces and/or routing, etc.) coupled to the virtual ground layer 102. In some examples, the process returns to block 704 of FIG. 7.

FIG. 9 is a flowchart representative of an example method 900 of manufacturing the example virtual ground layer 102 of FIGS. 1, 2, 3, 4 and/or 5 (e.g., in connection with block 810 of FIG. 8). In some examples, some or all of the operations outlined in the example method 900 are performed automatically by fabrication equipment that is programmed to perform the operations. Although the example method of manufacturing is described with reference to the flowchart illustrated in FIG. 9, many other methods may alternatively be used. For example, the order or execution of the blocks may be changed, and/or some of the blocks described may be combined, divided, re-arranged, omitted, eliminated, and/or implemented in any other way.

The example method 900 begins at block 902 by providing an example amorphous silicon layer (e.g., the first layer 202 of FIG. 2) on the dielectric layer 114. For example, one or more layers of amorphous silicon are provided (e.g., deposited, laminated) on the dielectric layer 114 to provide the amorphous silicon layer (e.g., the first layer 202). In some examples, the first layer 202 extends continuously across the entire area of the underlying dielectric layer 114 (e.g., without patterning).

At block 904, the example method 900 includes providing an example adhesive layer (e.g., the second layer 204 of FIG. 2) on the amorphous silicon layer. For example, one or more layers of titanium nitride are provided (e.g., deposited, laminated) on the amorphous silicon layer (e.g., the first layer 202) to provide the adhesive layer (e.g., the second layer 204). In some examples, the second layer 204 extends continuously across the entire area of the underlying first layer 202 (e.g., without patterning).

At block 906, the example method 900 includes providing an example metal layer (e.g., the third layer 206 of FIG. 2) on the adhesive layer. For example, one or more layers of metal material (e.g., tungsten, cobalt, molybdenum, aluminum, etc.) are provided (e.g., deposited, laminated) on the adhesive layer (e.g., the second layer 204) to provide the metal layer (e.g., the third layer 206). In some examples, the process returns to block 812 of FIG. 8. In some examples, the third layer 206 extends continuously across the entire area of the underlying second layer 204 (e.g., without patterning).

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of ±10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable voltage contrast inspection of an example test device (e.g., a test semiconductor device, a short-flow BEOL vehicle, etc.). Examples disclosed herein provide an example virtual ground layer (e.g., a conductive layer, a capacitive ground layer) between an insulating layer (e.g., a dielectric layer coupled to a substrate) and one or more process layers of the test device. In some examples, the virtual ground layer is electrically coupled to one or more conductive components (e.g., via(s), contact(s), traces, etc.) in the process layers to function as an electrical sink and/or to provide a replenishing supply of electrons to the conductive component(s). As a result, examples disclosed herein enable VC inspection to be performed on the test device, thus enabling detection of defects (e.g., unlanded vias, electrical opens, electrical shorts, etc.) that are typically undetectable using other known inspection techniques (e.g., optical inspection techniques). Advantageously, by enabling VC inspection on short-flow vehicles and/or devices (e.g., test devices that do not provide full functionality of a completed semiconductor device), examples disclosed herein enable errors in a fabrication process flow to be identified and/or corrected prior to fabrication of a corresponding full-flow semiconductor device, thus reducing time and/or material waste associated with correction and/or re-fabrication of the semiconductor device. Disclosed systems, apparatus, articles of manufacture, and methods are accordingly directed to one or more improvement(s) in the operation of a machine or other electronic and/or mechanical device.

Example methods and apparatus for voltage contrast defect inspection are disclosed herein. Further examples and combinations thereof include the following:

Example 1 includes an apparatus comprising a substrate, a virtual ground layer coupled to the substrate, and at least one process layer coupled to the virtual ground layer, the at least one process layer including a conductive feature.

Example 2 includes the apparatus of example 1, wherein the virtual ground layer is not electrically coupled to an electrical ground.

Example 3 includes the apparatus of example 1, further including an alignment mark layer coupled between the at least one process layer and the substrate, and a dielectric layer coupled to the alignment mark layer.

Example 4 includes the apparatus of example 1, wherein the virtual ground layer includes a metal layer.

Example 5 includes the apparatus of example 4, wherein the metal layer includes at least one of tungsten, cobalt, molybdenum, or aluminum.

Example 6 includes the apparatus of example 5, wherein the virtual ground layer includes a silicon layer, the silicon layer closer to the substrate than the metal layer.

Example 7 includes the apparatus of example 6, wherein the virtual ground layer includes an adhesive layer between the metal layer and the silicon layer.

Example 8 includes the apparatus of example 7, wherein the adhesive layer includes titanium and nitrogen.

Example 9 includes the apparatus of example 1, wherein a thickness of the virtual ground layer is 20 nanometers or less.

Example 10 includes the apparatus of example 1, wherein the virtual ground layer includes a first layer and a second layer, the first layer closer to the substrate than the second layer is to the substrate, the first layer having a first electrical resistance, the second layer having a second electrical resistance less than the first electrical resistance.

Example 11 includes an apparatus comprising a semiconductor wafer, and a conductive layer coupled to the semiconductor wafer, the conductive layer extending continuously across an area corresponding to a majority of a footprint of the semiconductor wafer, the conductive layer electrically isolated from the semiconductor wafer.

Example 12 includes the apparatus of example 11, further including an alignment mark layer and a dielectric layer coupled between the semiconductor wafer and the conductive layer.

Example 13 includes the apparatus of example 11, wherein the conductive layer includes at least one of tungsten, cobalt, molybdenum, or aluminum.

Example 14 includes the apparatus of example 11, wherein the conductive layer includes amorphous silicon.

Example 15 includes a method comprising performing voltage contrast inspection of a test device, the test device including a substrate, at least one metallization layer structured according to an interconnect design for a semiconductor device, and a virtual ground layer between the at least one metallization layer and the substrate, the virtual ground layer electrically isolated from the substrate, and detecting a defect in the test device based on results of the voltage contrast inspection.

Example 16 includes the method of example 15, further including detecting the defect by detecting that a conductive via intended, based on the interconnect design, to be coupled to the at least one metallization layer is not electrically coupled to the virtual ground layer.

Example 17 includes the method of example 15, further including detecting the defect by detecting at least one of an electrical short or an electrical open in the at least one metallization layer.

Example 18 includes the method of example 15, further including performing the voltage contrast inspection without electrically coupling the virtual ground layer to an electrical ground.

Example 19 includes the method of example 15, wherein a size of the defect is 5 nanometers or less.

Example 20 includes the method of example 15, further including adjusting a parameter of a fabrication process for the semiconductor device based on the defect, the test device to emulate a portion of the semiconductor device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a substrate;
a virtual ground layer coupled to the substrate; and
at least one process layer coupled to the virtual ground layer, the at least one process layer including a conductive feature.

2. The apparatus of claim 1, wherein the virtual ground layer is not electrically coupled to an electrical ground.

3. The apparatus of claim 1, further including:
an alignment mark layer coupled between the at least one process layer and the substrate; and
a dielectric layer coupled to the alignment mark layer.

4. The apparatus of claim 1, wherein the virtual ground layer includes a metal layer.

5. The apparatus of claim 4, wherein the metal layer includes at least one of tungsten, cobalt, molybdenum, or aluminum.

6. The apparatus of claim 5, wherein the virtual ground layer includes a silicon layer, the silicon layer closer to the substrate than the metal layer.

7. The apparatus of claim 6, wherein the virtual ground layer includes an adhesive layer between the metal layer and the silicon layer.

8. The apparatus of claim 7, wherein the adhesive layer includes titanium and nitrogen.

9. The apparatus of claim 1, wherein a thickness of the virtual ground layer is 20 nanometers or less.

10. The apparatus of claim 1, wherein the virtual ground layer includes a first layer and a second layer, the first layer closer to the substrate than the second layer is to the substrate, the first layer having a first electrical resistance, the second layer having a second electrical resistance less than the first electrical resistance.

11. An apparatus comprising:
a semiconductor wafer; and
a conductive layer coupled to the semiconductor wafer, the conductive layer extending continuously across an area corresponding to a majority of a footprint of the semiconductor wafer, the conductive layer electrically isolated from the semiconductor wafer.

12. The apparatus of claim 11, further including an alignment mark layer and a dielectric layer coupled between the semiconductor wafer and the conductive layer.

13. The apparatus of claim 11, wherein the conductive layer includes at least one of tungsten, cobalt, molybdenum, or aluminum.

14. The apparatus of claim 11, wherein the conductive layer includes amorphous silicon.

15. A method comprising:
performing voltage contrast inspection of a test device, the test device including:
a substrate;
at least one metallization layer structured according to an interconnect design for a semiconductor device; and
a virtual ground layer between the at least one metallization layer and the substrate, the virtual ground layer electrically isolated from the substrate; and
detecting a defect in the test device based on results of the voltage contrast inspection.

16. The method of claim 15, further including detecting the defect by detecting that a conductive via intended, based on the interconnect design, to be coupled to the at least one metallization layer is not electrically coupled to the virtual ground layer.

17. The method of claim 15, further including detecting the defect by detecting at least one of an electrical short or an electrical open in the at least one metallization layer.

18. The method of claim 15, further including performing the voltage contrast inspection without electrically coupling the virtual ground layer to an electrical ground.

19. The method of claim 15, wherein a size of the defect is 5 nanometers or less.

20. The method of claim 15, further including adjusting a parameter of a fabrication process for the semiconductor device based on the defect, the test device to emulate a portion of the semiconductor device.
